(19) United States
(12) Patent Application Publication
(10) Pub. No.: US 2008/0203405 A1
(43) Pub. Date: Aug. 28, 2008

(54) Method for Preparing an Electric Circuit Comprising Multiple Leds

(76) Inventor: Johannes Otto Rooymans, Ermelo (NL)

Correspondence Address: HOWREY LLP-EU, C/O IP DOCKETING DEPARTMENT, 2941 FAIRVIEW PARK DR., SUITE 200, FALLS CHURCH, VA, 22042, US

(21) Appl. No.: 11/997,932

(22) PCT Filed: Aug. 4, 2006
(86) PCT No.: PCT/IB2006/055060

§ 371 Date: Feb. 5, 2008

(30) Foreign Application Priority Data
Aug. 5, 2005 (NL) 1029688

(51) Int. Cl. H01L 33/00; H01L 21/00

(52) U.S. Cl. 257/91; 438/33; 257/E33.001; 257/E21.001

(57) ABSTRACT

The invention relates to a method for preparing an electric circuit comprising a plurality of Light-Emitting Diodes (LEDs). First, a continuous layer of a first semiconductor material is provided. On this a first pattern of a material of a second semiconductor type is applied. Next, a substrate comprising a second pattern of at least one conducting layer (34) is attached to the first pattern. After this, the continuous layer is cut according to a third pattern. Thus the plurality of LEDs is formed.

### BACKGROUND OF THE INVENTION

The present invention relates to an electric circuit comprising at least one semiconductor component. A circuit for which the present invention is suitable is described in Dutch application NL1027960. In this application, which is incorporated herein by reference in its entirety, a bridge circuit is described, among others, having such a set up that at least four rectifiers, preferably diodes, supply a rectified current to at least one lighting element. The manufacture of such a bridge circuit with a number of diode components, such as Light-Emitting Diodes (LEDs) in chips is time-consuming because the chips must be placed by a placing apparatus in the proper orientation, which differs for the respective diodes, while in the current methods they are supplied in the same orientation. Connecting all components is also complex. This complexity leads to long connections between components. Due to the long connections additional energy losses occur and unnecessary heat is generated.

### SUMMARY OF THE INVENTION

The invention aims at realizing a more efficient circuit in which the length of the connections can be reduced and also the production efficiency of the electric components in a circuit can be improved. This aim is achieved by providing a method for preparing an electric circuit comprising a plurality of LEDs, which comprises the following steps:

a) providing a continuous layer of a first semiconductor material;
b) providing a layer of a second semiconductor material in a first pattern, adjacent to the continuous layer;
c) providing a substrate with a layer of a conducting material in a second pattern;
d) attaching the layer of the second semiconductor material in the first pattern to the layer of the semiconductor material in the second pattern; and
e) cutting the continuous layer to form individual LEDs.

In a preferred embodiment such a first semiconductor material is chosen that the LED formed emits light of a certain color. To generate green light this continuous layer may contain Indium Gallium Nitride (InGaN) and/or Silicon Carbide (SiC). To generate red or amber light the layer may contain Aluminum Gallium Indium Phosphide (AlGaInP), Gallium Phosphide (GaP) and/or a combination thereof, among others.

The continuous layer is formed using known prior art methods. A known method is growing epitaxial crystals. To obtain a suitable conductivity of this layer it is doped with atoms providing n-type or p-type conduction. Preferably, the layer is an n-type semiconductor. To realize this, additional nitrogen (N) atoms, for example, might be involved in growing the epitaxial crystals.

The second semiconductor material is of the type opposite to the continuous layer. This means that, if the continuous layer is an n-type semiconductor, the layer with the first pattern is made of a p-type semiconductor material. This could be done by diffusion of aluminum (Al) or boron (B) atoms at suitable temperatures. This layer is usually only a few microns thick. To substantially level the resulting structure, the applied layer of p-type semiconductor material may be lapped.

The layer can be provided with the pattern by any appropriate method. The second semiconductor type may, for example, be applied selectively on the continuous layer using masks, thereby obtaining the desired pattern directly. It is also possible to initially apply the second semiconductor layer as a continuous layer. Subsequently, by selectively removing material, for example by etching, the desired pattern can be obtained. The various available methods are well known in semiconductor technology and need no further explanation here.

If so desired, the continuous layer itself may be applied to a substrate. In this case the layer of the second semiconductor material is applied on the side of the continuous layer that is opposite to the substrate. Preferably the substrate is transparent for visual light. Sapphire (a transparent form of aluminum oxide) is particularly suitable for this purpose.

Next, the substrate is provided with a pattern of conducting material. It will be clear that the substrate itself consists of an insulating material. The pattern choice for the conducting material is such that, after attaching to the layer of the second semiconductor material, the desired diode circuit is created. As a result no change in the orientation of the diodes is necessary.

Subsequently, the substrate is attached with its conducting layer side to the second layer. This is to create an electric contact between the second semiconductor layer and, for example, external soldering points. It might be preferable to provide the second semiconductor layer with a conducting material before attaching, to create a better electric contact.

The continuous layer is cut to form individual LEDs. In this context the term “cutting” comprises every suitable method for selectively removing the first semiconductor material down to a depth of at least the thickness of the continuous layer, thus creating mutually isolated islands of the first semiconductor material. Examples of suitable methods comprise laser cutting, plasma cutting, and even machining.

Depending on whether or not the continuous layer has been applied to a substrate, the continuous layer is cut before or after the substrate with the pattern of conducting material is attached. In other words, if the continuous layer is applied to a substrate, the continuous layer is cut first, before the substrate with the conducting pattern is attached, i.e., step e) is performed before step d). If the continuous layer is not applied to a substrate, step d) is performed first, followed by step e).

The invention also relates to an electric circuit comprising a plurality of LEDs made with the method according to the invention.

### BRIEF DESCRIPTION OF THE DRAWINGS

Below, the invention will be exemplified using the following figures. The figures are not meant to limit the scope of the invention, but merely serve as illustration.

FIG. 1 shows a diagram of a circuit with a diode-bridge circuit;

FIG. 2a shows a diagram of a possible implementation of the diode-bridge circuit of FIG. 1;

FIG. 2b shows another representation of the possible implementation of the diode-bridge circuit of FIG. 2a;

FIGS. 3a-3b show diagrams of a method for preparing a diode-bridge circuit according to a first embodiment of the invention;

FIG. 4 shows a method for connecting two structures, which can be used in the method shown in FIGS. 3a-e;

FIGS. 5a-f show diagrams of a method for preparing a plurality of individual LEDs arranged for use in a diode-bridge circuit according to a second embodiment of the invention;

FIG. 6a shows a top view diagram of a pattern of electric traces corresponding with a diode-bridge circuit as shown in FIG. 2b;

FIG. 6b shows an equivalent circuit diagram of the pattern of electric traces of FIG. 6a;

FIGS. 7a-c show different circuit diagrams that can be used in a direct current branch of the diode-bridge circuit as shown in FIG. 2b; and

FIGS. 8a, 8b, respectively, show a circuit diagram, and a pattern of electric traces of four diode-bridge circuits connected in parallel, which can be prepared using the present invention.

### DESCRIPTION OF SPECIFIC EMBODIMENTS

The invention will be illustrated further by a number of specific embodiments. It will be clear that the invention is not limited to these embodiments.

In a first embodiment the invention relates to a method comprising the following steps:
providing a first substrate comprising an emitting side and an attachment side, in which the first substrate comprises a first layer of a first semiconductor type and a second layer of a semiconductor type according to a first pattern, in which the second layer is disposed on the attachment side of the first substrate;
attaching the attachment side of the first substrate to the second substrate, the second substrate being insulating and provided with a second pattern of at least one conducting layer; and
cutting the first substrate from the emitting side of the first substrate down to the second pattern of the at least one conducting layer according to a third pattern, forming the plurality of LEDs.

Because the second pattern of the at least one conducting layer on the second substrate provides for the forming of connections between the LEDs, the LEDs need not be placed in any particular orientation.

In a preferred embodiment the attachment side of the first substrate is provided with a fourth pattern of at least one conducting layer, before attachment. The presence of this at least one conducting layer improves the optical properties of the LEDs, due to the layer's being reflective to a certain extent. Furthermore, the at least one conducting layer provides a contact area for heat transfer, after attachment.

Attaching of the attachment side of the first substrate to the second substrate may be performed with the aid of so-called bumps. When using bumps, attaching is relatively simple and, among other things, ensures that all electric connections are present at only one side of the plurality of LEDs, as a result of which these connections do not form an obstacle for the light emitted by the LEDs. Furthermore, with the aid of said bumps the first and second substrate can be disposed at an adjustable distance from each other, as a result of which possible damage to the second pattern of the at least one conducting layer on the second substrate during the cutting step may be limited as much as possible.

Preferably, the bumps comprise at least bumps of a first and second size. Upon attachment the bumps of the first size make contact with the first layer of the first semiconductor type, and the bumps of the second size make contact with the second layer of the second semiconductor type. The size difference enables a good connection with the first layer of the first semiconductor type, as well as the second layer of the second semiconductor type, if these two layers are not disposed in the same horizontal plane.

Preferably the first size is larger than the second size. Although a connection using bumps is generally less heat-conducting than connections established by soldering of one or more conducting layers on the second pattern of at least one conducting layer on the second substrate, such a size distribution is possible because most of the heat is generated at junctions between materials of the first semiconductor type and materials of the second semiconductor type. Preferably, because the areas of the second semiconductor type have to dissipate most of the heat, the bumps connecting the layer of the second semiconductor type, i.e. the bumps of the second size, are not of too large a size.

To improve the optical properties of the LEDs it is possible to form, at least before cutting, a connection of the emitting side of the first substrate with a third insulating substrate, the third substrate being transparent for a wavelength that can be generated by at least one of the plurality of LEDs. A possible material for the third substrate is sapphire. Because in this case the sapphire is also cut when the LEDs are separated, the light-emitting area of the LEDs is increased.

In a second embodiment the invention relates to a method for preparing an electric circuit comprising a plurality of LEDs, in which the method comprises the following steps:
providing a first insulating substrate transparent for a wavelength that can be generated by at least one of the plurality of LEDs;
forming a layer on the first insulating substrate, comprising a first layer of a first semiconductor type, and a second layer of a second semiconductor type;
selectively removing the second layer according to a first pattern, until part of the first layer is exposed, and at least by grooves an isolated area of the second semiconductor type is formed;
selectively applying at least one conducting layer according to a second pattern, thereby making a first connection with the first layer of the first semiconductor type and a second connection with the isolated area of the second semiconductor type;
cutting through the at least one conducting layer, the second layer of the second semiconductor type, and the first layer of the first semiconductor type, down to the first insulating substrate according to a third pattern, thereby forming the plurality of LEDs; and
attaching the at least one conducting layer to the first insulating substrate with the second insulating substrate containing a third pattern of at least one conducting layer, thereby forming at least one conducting contact between the at least one conducting layer on the first insulating substrate and the at least one conducting layer on the second insulating substrate.

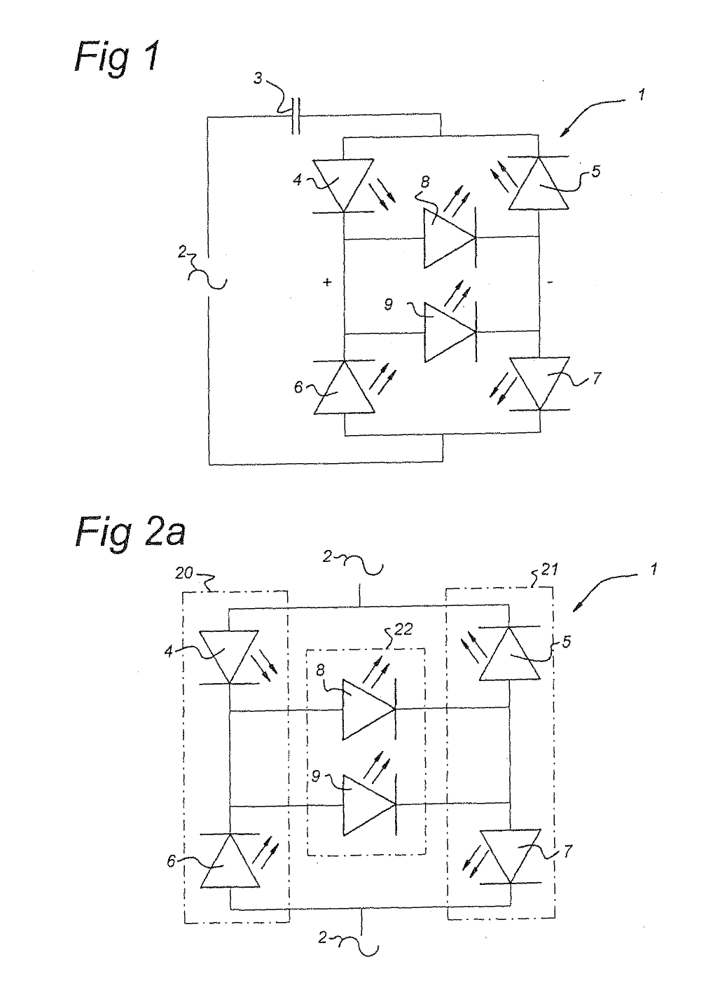

FIG. 1 shows a circuit diagram with a diode-bridge circuit 1. In said circuit an alternating current network 2 is connected with a capacitor 3. The diode-bridge circuit 1 is connected in series with capacitor 3. The diode-bridge circuit 1 in FIG. 1 comprises four Light-Emitting Diodes (LEDs) 4, 5, 6, 7 causing two-phase rectification of the current through a central current branch, which may comprise one or more electric components connected in an electric circuit. In this case the central current branch comprises two parallel connected LEDs 8, 9. Because the LEDs 8, 9 are charged in both phases of the alternating current in pass direction, the light emitted by the LEDs 8, 9 will have a substantially constant intensity.

A circuit as shown in FIG. 1 may be prepared by placing individual diodes on a substrate. Because diodes in chip embodiment are normally supplied to a placing apparatus on a reel, which is to say, on a long liner, in a set, identical orientation, the placing apparatus usually has to turn the diodes before they can be placed on the substrate. This additional handling is at the expense of speed and accuracy. Consequently, the productivity of the placing apparatus decreases. Furthermore, connecting all electric components in the circuit is complex, because, among other things, contacts between bondings must be avoided. This complexity often leads to long bondings between several electric components. Because of said long bondings a relatively large energy loss occurs, and unwanted extra heat is generated.

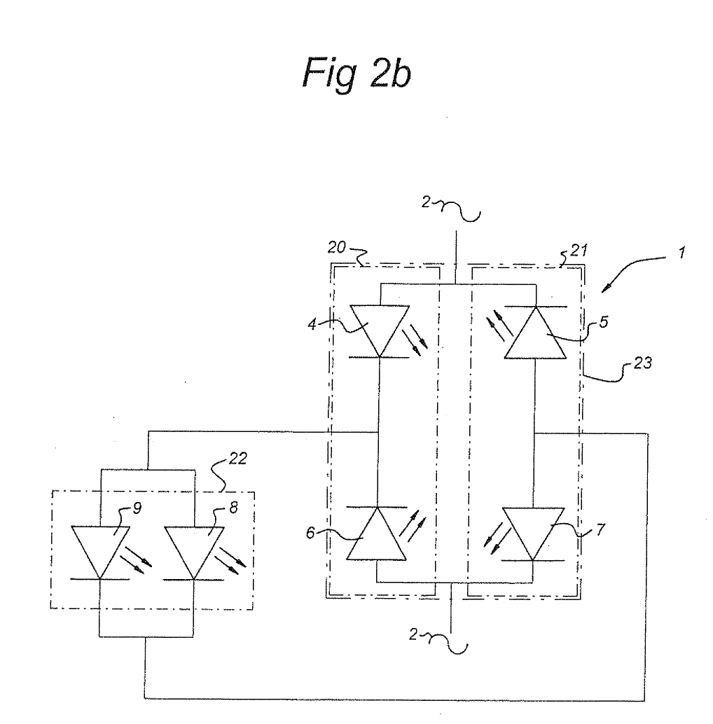

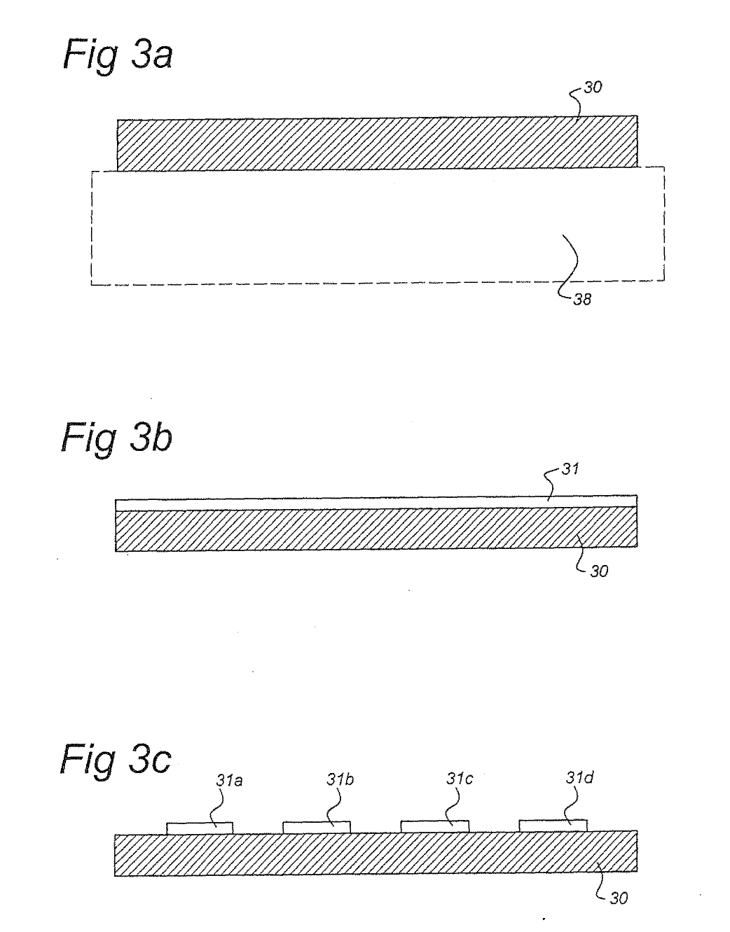

FIG. 2a again shows the diode-bridge circuit of FIG. 1 with the centrally charged LEDs 8, 9, the circuit being divided in three groups 20, 21, 22. The rectangles 20, 21, 22, indicated by dotted lines, each group together two LEDs. Dutch application NL1027961, which is incorporated herein by reference in its entirety, discloses that groups like these, containing two diodes, may be replaced by pnp-diodes, or by npn-diodes, as the case may be. By such a replacement the number of components of a circuit may be reduced. However, further investigations have shown that an even simpler replacement with even less components is possible.

This is shown in FIG. 2b, in which the same circuit is shown as in FIG. 2a, including the same groups. In this circuit the LEDs are grouped in group 22, which corresponds with the same group in FIG. 2a, and group 23, comprising groups 20, 21, and therefore LEDs 4, 5, 6, 7. LEDs 4, 5, 6, 7 together form a single diode-bridge circuit. However, the arrangement of the groups is such that replacement of the individual LEDs 4, 5, 6, 7 by a single structure still further simplifies the preparation of circuits as shown in FIG. 1.

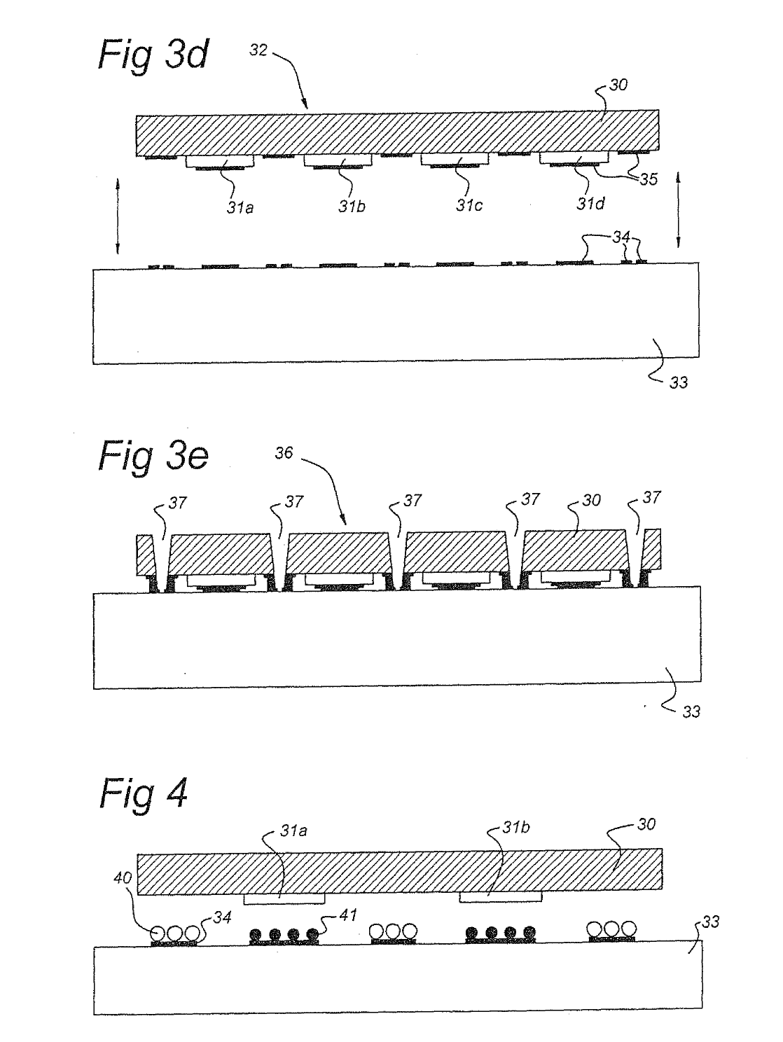

FIGS. 3a-e show diagrams of a method for preparing a plurality of individual LEDs arranged for use in a diode-bridge circuit according to a first embodiment of the present invention. First of all, a substrate 30 of semiconductor material is provided, as shown in FIG. 3a. Suitable materials for this substrate 30 depend on the desired wavelength band emitted by the LED when in use. For generating green light substrate 30 may contain Indium Gallium Nitride (InGaN) and/or Silicon Carbide (SiC). For generating red or amber light substrate 30 may contain Aluminum Gallium Indium Phosphide (AlGaInP), Gallium Phosphide (GaP) and/or a combination of these, among others.

The substrate 30 is formed using known prior art methods. A known method is growing epitaxial crystals. To obtain a suitable conductivity of substrate 30, it is doped with atoms ensuring n-type or p-type conduction. Preferably, substrate 30 is an n-type semiconductor. To realize this, nitrogen (N) atoms could for example be added during the growth of the epitaxial crystals. Next, as shown in FIG. 3b, a layer 31 of p-type semiconductor material is formed. This could be done by diffusion of aluminum (Al) or boron (B) atoms at suitable temperatures. Herein the p-type semiconductor material 31 will be referred to as the p-layer. Generally, the p-layer formed is only a few microns thick. To substantially level the resulting structure, the applied layer 31 of p-type semiconductor material may be lapped.

Next, p-type semiconductor material is selectively removed in the p-layer 31, for example by etching a pattern using a mask, until a desired area of base substrate 30 is exposed (FIG. 3c). In an alternative embodiment of the present invention, which is not shown, the p-layer is formed selectively, for example by using masking methods known to a person skilled in the art. By selectively removing p-type semiconductor material, isolated areas 31a-d are formed of p-type semiconductor material.

Prior to performing the above method, the side of the substrate 30 of n-type semiconductor material on which no p-layer 31 is applied, can be bonded to a substrate 38 of insulating material, shown in FIG. 3a as a rectangle with a broken outline, to promote the optical properties of the LEDs. This substrate 38 of insulating material is substantially transparent for one or more wavelengths of the light emitted by the individual LEDs. Herein this substrate 38 will be referred to as transparent substrate 38. A suitable material is for example sapphire.

Next a second substrate 33 of insulating material is provided. This second substrate 33, as shown in FIG. 3d, is attached opposite to the inverted structure 32 as obtained in FIG. 3c. Preferably, electric traces 34 are applied on one side, i.e. the side facing structure 32, of the second substrate 33, which together form a pattern which is suitable for enabling the desired connections between LEDs, such as LEDs 4, 5, 6, 7 in the diode-bridge circuit of FIG. 1, and external contacts, for example with LEDs 8, 9 in FIG. 1.

Preferably, the second substrate 33 is made of a material with a small coefficient of thermal extension and good heat conduction, for example ceramics or aluminum. In case of an aluminum second substrate 33, at least one side of the substrate 33, preferably the side to be connected with the structure 32, is hard anodized down to a depth of 20-100 μm. Typically, the thickness of the second substrate 33 is 1-5 mm. These measures ensure a high breakdown voltage, i.e. higher than 1 kV.

Incidentally, one should note that the dimensions shown of the second substrate 33, in comparison to the dimensions of the structure 32, in many cases do not correspond with the final embodiment, but are only drawn this way to elucidate the present invention. Normally, second substrate 33 is much larger than structure 32, in thickness as well as diameter.

Preferably, the electric traces 34 comprise a metallic layer of copper (Cu), silicon (Si), or a combination of both. Cu offers good electric and heat conductance. Si is useful because its expansion coefficient is approximately equal to the typical expansion coefficient of a LED. Consequently, fewer mechanical stresses will arise.

To enable a connection between the second substrate 33 and structure 32, the first substrate 30 and the areas of p-type semiconductor material 31a-d preferably are provided with a conducting layer 35, also called under-metalizing, according to a suitable pattern, for example using masks or other methods known to the person skilled in the art. Thus, electric contact points are prepared. In applying the conducting layer 35 it is important no conducting connection is created between the isolated areas 31a-d of p-type semiconductor material and the substrate 30 of n-type semiconductor material. In FIG. 3d the isolated areas 31a-d of p-type semiconductor material, as well as the substrate 30, are covered with the same conducting layer 35. However, it is also possible that different kinds of conducting material are applied in different locations. Alternatively, several conducting layers 35 can be super-positioned. It is for example possible to subsequently apply a chromium layer (Cr), a molybdenum layer (Mo), and a silver layer (Ag). If necessary, for example due to the presence of a short-circuit through conducting layer 35 between isolated areas 31a-d and/or the substrate 30, the conducting layer 35 can be selectively removed using known methods, such as etching. Depending on its location, the conducting layer 35 can serve either as a p-electrode, i.e. an electrode making contact with one of the isolated areas 31a-d, or as a n-electrode, an electrode making contact with the substrate 30 of n-type semiconductor material.

The contacts on the substrate 30 of n-type semiconductor material can be provided with a conducting material up to a substantially equal height as areas 31a-d. When contacts created in this manner are connected to an electric circuit, a more even distribution of the current in the substrate 30 of n-type semiconductor material will occur in use, causing a more even distribution of the light output at pn-junctions between substrate 30 and isolated areas such as 31a-d.

Preferably, the area of the conducting traces 34 at locations of the second substrate 33, where a connection with the conducting layer 35 on the first substrate 30 and the areas 31a-d occurs, is smaller than that of the electric contacts formed by the conducting layer 35. The advantage being that, when attaching by for example soldering, the risk of a short circuit between the substrate 30 of n-type semiconductor material and the areas 31a-d, can be kept to a minimum. The other side of the second substrate 33 can be covered with an additional conducting layer, for example copper (Cu), having the primary function of dissipating heat.

The connection of the created structures of FIG. 3d may be realized using known methods, such as soldering with an Au—Sn-solder at suitable temperatures, for example 278° C.

If desired, several additional layers may be disposed between substrate 30 of n-type semiconductor material and the areas 31a-d of p-type semiconductor material, of course. Examples are one on more so-called clad layers for optical improvement and/or conduction active layers.

After forming a common structure 36, it is cut according to a preferably regular pattern (FIG. 3e). The cutting takes place from the side of the substrate 30 of n-type semiconductor material and the cutting planes run down to at least the electric traces 34. This way individual LEDs, such as LEDs 4, 5, 6, 7 in FIG. 1, may be obtained. Preferably, the cutting takes place using a laser, but other forms of cutting such as plasma cutting and in some cases even machining, can be suitable. In cutting it is important that the cut-away conducting materials, for example originating from the conducting layer 35 or one of the electric traces 34, do not cause a short circuit between the n-type semiconductor material and the p-type semiconductor material. Consequently, preferably as few of the cutting lines as possible lie at positions where the electric traces 34 are present. Preferably, the cuts have a width of less than 40 microns.

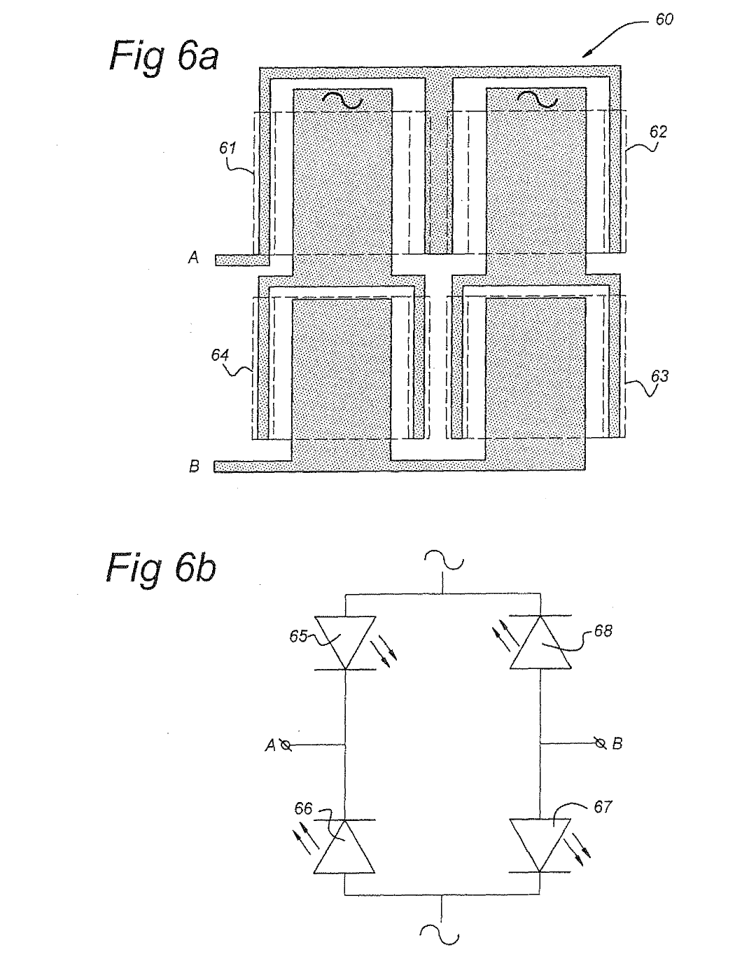

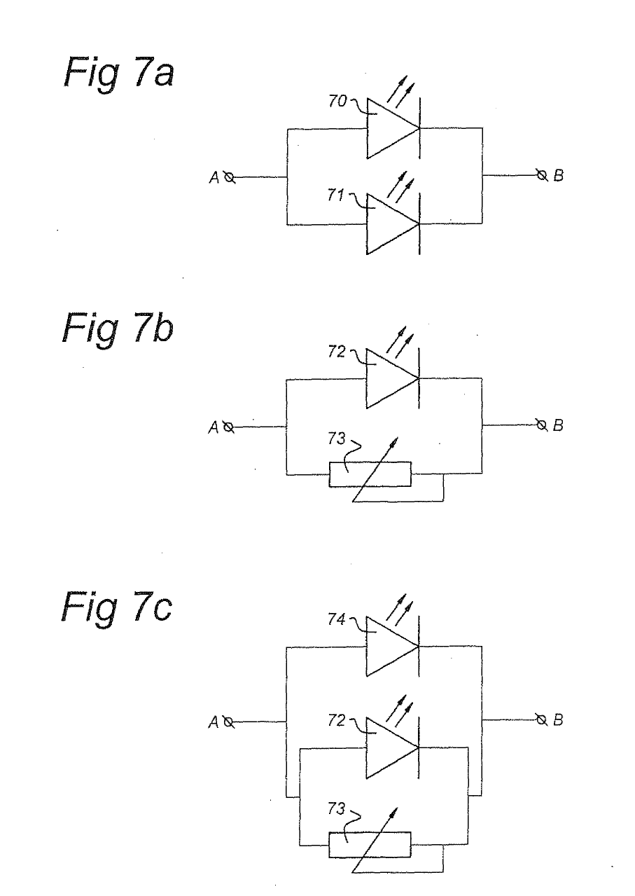

In one embodiment, in which structure 32 also comprises a transparent substrate 38, as described earlier, the cutting yields an additional advantage, the outer surface of the transparent substrate 38 of insulating material being enlarged by the cutting. Consequently, the exit area for light of this transparent substrate 38 is enlarged, increasing the overall light output of a diode-bridge circuit as shown in FIG. 6b.

The circuit formed can be protected with a protective cover (not shown) as described in Dutch application NL1027961.

Because the electric traces 34 on the second substrate 33 provide the above connections, the LEDs need not be placed in a specific orientation. The circuit formed merely requires one time placing of a piece of semiconductor material, and the LED-diode-bridge circuit is formed only after placing and attaching.

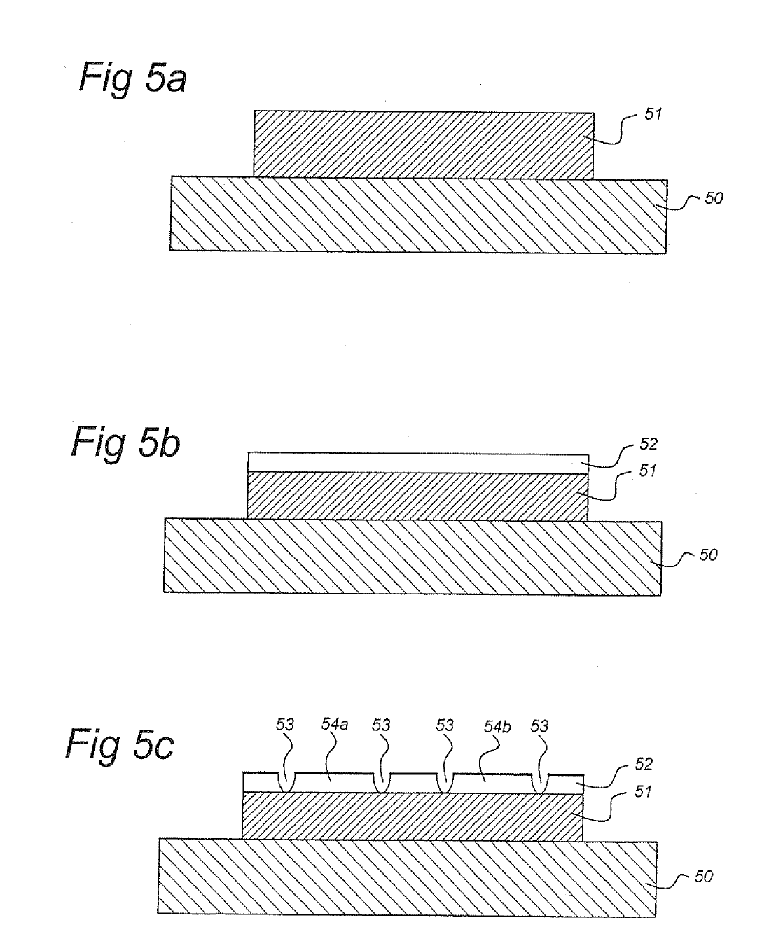

FIG. 4 shows an alternate form for the connection of structure 32 and second substrate 33 as shown in FIG. 3d. In this connection method so-called “bumps” 40, 41 are used. As a rule, bumps 40, 41 are preferably spherical particles of conducting material, which are applied locally on the surface, creating a local elevation of the substrate.

Bumps 40, 41 are applied on the electric traces 34 and/or conducting layer 35. The local application of bumps 40, 41 can be performed with methods known to the person skilled in the art, such as vapor deposition, galvanization, stenciling, etc. Bumps offer the advantage that in connecting structure 32 with the second substrate 33 structure 32 is kept at a specific distance from electric traces 34, usually the bump height. This distance facilitates leaving the electric traces 34 undisturbed when cutting structure 36.

Because structure 36 surfaces, due to the alternating of areas of p-type semiconductor material 31a-d and parts of the substrate 30 of n-type semiconductor material, the overall surface of the structure 32, which must be connected, is not flat. It might be possible to keep the distances between the areas of p-type semiconductor material 31a-d and the parts of the electric traces 34 they are connected to, equal to the distance between the parts where the substrate 30 of n-type semiconductor material surfaces and the parts of the electric traces 34 they are connected with, by providing the relevant trace parts with different thicknesses. However, it is simpler to obtain a good connection of the insulating substrate 33 with electric traces 34 by, as shown in FIG. 4, using larger bumps for the connection with n-type semiconductor material than for the connection with the p-type semiconductor material. In this case is also possible that the n-bumps 40 (white spheres in FIG. 4), i.e. bumps applied for the connection of substrate 33 with the n-type semiconductor material of structure 32, have a material composition different from the p-bumps 41 (black spheres in FIG. 4), the bumps for the connection of substrate 33 with areas of p-type semiconductor material 32a, 32b on structure 32.

The use of bumps eliminates the need of electrically connecting the several contacts with bondings on the top of the formed LEDs. Particularly suitable materials are, among others, gold, and polymers comprising one or more of the group consisting of conducting epoxy, polysulfone, and polyurethane. Contrary to many other materials, gold has relatively good adhesion properties, eliminating the need of metalizing the layer to be attached before applying the bumps. Bumps of polymers can be applied in lithographic patterns by stenciling, and are therefore easy to use. Furthermore, bumps of polymeric materials have favorable elastic properties. Although a connection using bumps usually conducts less heat than a connection established by soldering one or more conducting layers, it is anticipated that a connection using bumps is possible anyway, because most of the heat is developed at material junctions from p-type semiconductor material to n-type semiconductor material. Because the n-type semiconductor material parts need to dissipate less heat, the n-bumps can have a larger size.

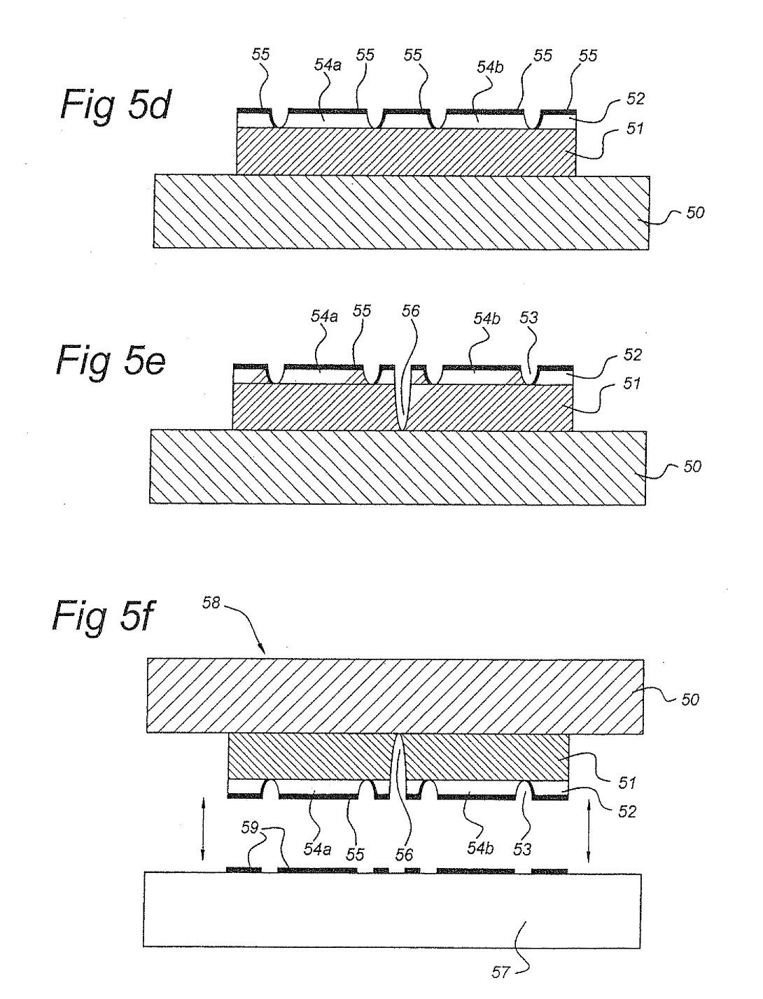

FIGS. 5a-f show a diagram of a method for preparing a plurality of individual LEDs arranged for use in a diode-bridge circuit according to a second embodiment of the present invention. First of all, a base substrate 50 of an insulating material is provided which is virtually transparent for one or more wavelengths of the light emitted by the individual LEDs, such as sapphire. On this base substrate 50, a layer 51 of n-type semiconductor material is applied, which will be referred to herein as the n-layer 51, (FIG. 5a), using methods known to the person skilled in the art.

Next, in the upper part of this n-layer, a layer 52 of p-type semiconductor material is formed, which will be referred to herein as the p-layer 52 (FIG. 5b), using prior art methods. The materials used for the semiconductor in layer 52, as well as the n/p-donor atom elements present therein, can be chosen identical to those described in connection with FIGS. 3a-e. To substantially level the surface of the resulting structure, the applied p-layer 52 can be lapped.

Next, in this p-layer 52 p-type semiconductor material is selectively removed, for example by etching a pattern using a mask, until a desired area of the n-layer 51 is exposed (FIG. 5c). By selectively removing p-type semiconductor material, grooves 53 are made, which extend to n-layer 51, thus forming isolated areas 54a, 54b of p-type semiconductor material.

Now a suitably conducting layer 55 is selectively applied (FIG. 5d), for example using shadow masks. When applying this layer, it is important that no conducting connection be created between the areas 54a, 54b of p-type semiconductor material and the n-layer 51. In FIG. 6d the areas 54a, 54b of p-type semiconductor material, as well as the grooves 53, are covered with the same conducting layer 55. However, it is also possible that different types of semiconductor material are applied on different locations. Alternatively, several conducting layers 55 can be super-imposed. Thus, it is for example possible to subsequently apply a chromium layer (Cr), a molybdenum layer (Mo), and a silver layer (Ag). If necessary, for example due to the presence of a short circuit through conducting layer 55 between the areas 54a, 54b and/or the n-layer 51, the conducting layer 55 may selectively be removed using known methods, such as etching. Depending on its location the conducting layer 55 may function as a p-electrode as well as an n-electrode, the p-electrode and n-electrode having the same definition as given in relation to the embodiment of FIGS. 3a-e.

Contrary to the method shown in FIGS. 3a-e, the conducting layer 55 is already cut according to a preferably regular pattern (FIG. 5e) after applying. Also, the cutting is not performed from the n-layer 51 side, but from the p-layer 52 side where at this point areas 54a, 54b are present. Every cut 56, one of which is shown in FIG. 5e, extends to at least the base substrate 50. In this way individual LEDs, such as LEDs 4, 5, 6, 7 in FIG. 1, are obtained. Preferably, the cutting takes place using a laser, but other forms of cutting, such as plasma cutting, and in some cases even machining, are also considered. During cutting it is important that cut away conducting material, originating in conducting layer 55, does not cause a short circuit between the n-layer 51 and the areas 54a, 54b of p-type semiconductor material. Therefore, conducting layer 55 is applied in such a way that its presence on cutting line positions is kept to a minimum. Next, as shown in FIG. 5f, a second substrate 57 of insulating material is provided, which corresponds, with regard to its properties, to the second substrate 33 of FIG. 3e. This second substrate 57 is shown in FIG. 5f opposite to the inverted structure 58 of FIG. 5e. Preferably, electric traces 59 are applied on one side of the second substrate 57 only, together forming a pattern suitable for making the desired connections. Electric traces 59 correspond, with regard to their properties, to traces 34 in the embodiment of the invention shown in FIG. 3. The pattern of electric traces 59 may be prepared using prior art methods. Preferably the area of the conducting traces 59 at the locations where connection with the structure 58 takes place, is smaller than the relevant contact area on this structure 58. This has the advantage that in attaching by for example soldering, the risk of a short circuit between the n-layer 51 and the areas 54a, 54b of p-type semiconductor material can be kept to a minimum. Just as in the embodiment of FIG. 3, the other side of the second substrate 57 may be covered with a conducting layer (not shown), for example copper (Cu), having the primary function of dissipating heat.

Of course, several additional layers may be disposed between the n-layer 51 and the areas 54a, 54b of p-type semiconductor material, if desired. Examples are one or more clad layers for optical improvement and/or active layers, such as known to the person skilled in the art.

Finally, the structure formed by joining structure 58 and the second substrate 57 provided with the electric traces 59, is cut into pieces (not shown), for example pieces with four LEDs each, such as LEDs 4, 5, 6, 7 in the diode-bridge circuit of FIG. 1. Cutting structure 36 to pieces can be done in a way identical to the cutting for separating off individual diodes as shown in FIG. 5e.

The formed circuit may be protected with a protecting cover (not shown) as described in Dutch application NL1027961.

Once again, the LEDs need not be placed in a specific orientation, because the electric traces 59 on the second substrate 57 ensure the above connections.

FIG. 6a shows a top view diagram of a pattern of electric traces 60 corresponding to a diode-bridge circuit as comprised by frame 23 in FIG. 2b. The dotted outlines 61, 62, 63, 64 correspond to the positions of four LEDs to be placed. An equivalent circuit diagram of this trace pattern, including the placed LEDs 61, 62, 63, 64, is shown in FIG. 6b. The small areas in the dotted outlines 61, 62, 63, 64, correspond to a provision for a connection with n-type semiconductor material, while the large areas correspond to isolated areas of p-type semiconductor material. The connections for the direct current branch, between which, in the bridge circuit of FIG. 1, LEDs 8, 9 are disposed in parallel, are indicated with A and B, respectively, and reside on the outside of the circuitry. Thus, supplying an electric connection with one or more external components, such as LEDs 8, 9, becomes relatively simple.

As can be seen in FIG. 6a, the contact areas of the trace pattern beneath the large areas with p-type semiconductor material are large. Due to the large surface area, the heat dissipating capacity is increased.

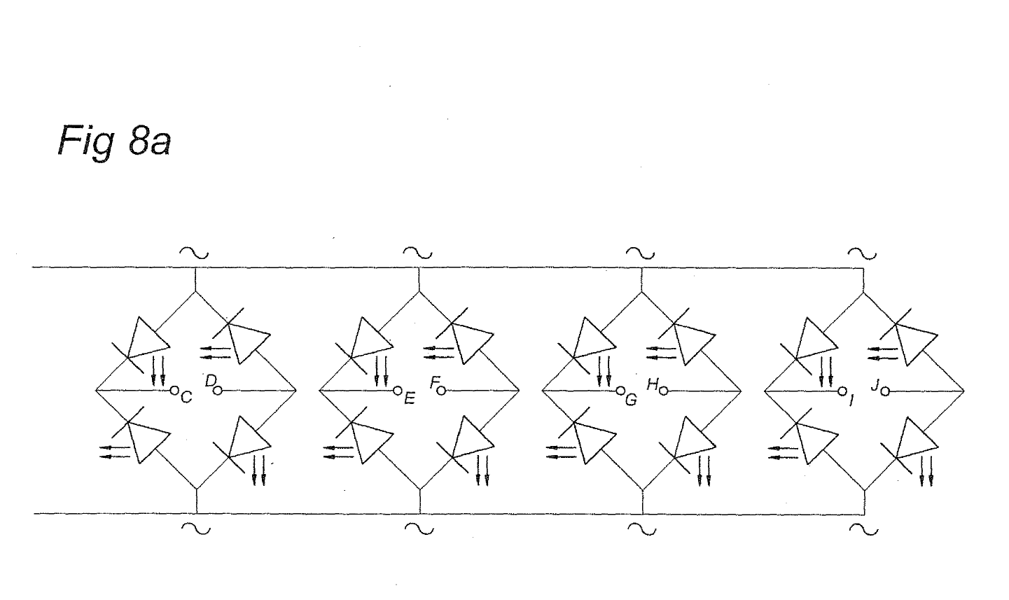

FIGS. 7a-c show several circuit diagrams that may be connected in the direct current branch between the connections A and B. FIG. 7a shows a circuit as used in the circuitry of FIG. 1, in which two LEDs 70, 71 are connected in parallel. These LEDs 70, 71 need not emit the same color of light as the LEDs 65, 66, 67, 68 in the bridge circuit as shown in FIG. 6b. As already described in Dutch patent application NL1027960, when multiple LEDs are used, which is the case when using a bridge circuit with four LEDs, in which in the direct current branch another two LEDs are connected in parallel, by choosing LEDs arranged to emit suitable wavelengths, the color of the light emitted by the overall circuitry can be affected. For example, if the four LEDs 65, 66, 67, 68 in the bridge circuit of FIG. 6b are arranged to emit light with a wavelength in the area of 590 nm, i.e. amber light, and the parallel connected LEDs 70, 71 in FIG. 7a emit green light, i.e. light with a wavelength of about 525 nm n, and blue light, i.e. light with a wavelength of about 470 nm, respectively, the overall circuit can emit white light when the intensities of all LEDs 65, 66, 67, 68, 70, 71 in the circuit are suitably proportioned.

The emitted light can be affected further by placing a variable resistor 73 in parallel to one or more of LEDs 70, 71, 72, as shown in FIGS. 7a and 7b. By varying the value of resistor 73, the color of the light emitted by overall circuit can be affected. The variable resistor 73 can be a potentiometer, for example. Alternatively, considering the power that can be induced in the variable resistor 73, a power transistor may be used, controlling the base with a smaller current using a potentiometer.

The circuit diagram shown in FIG. 7b may be used in applications in lamps for nocturnal lighting as mentioned in Dutch patent application NL1029231, among others. In this case the four LEDs 65, 66, 67, 68 of the bridge circuit as shown in FIG. 6b, are arranged to emit light with a wavelength between 480 and 550 nm, i.e. greenish light. Preferably, to provide greater visual contrast, light with a wavelength between 570-610 nm, i.e. amber light, is “mixed” in. This could be done by using a circuit diagram as shown in FIG. 7a. The full added amount of amber light is not always necessary. Accordingly, a circuit with a variable resistor as shown in FIG. 7b, is very useful to control the amount of amber light mixed in with the greenish light, depending on the location of the lamp and the local circumstances.

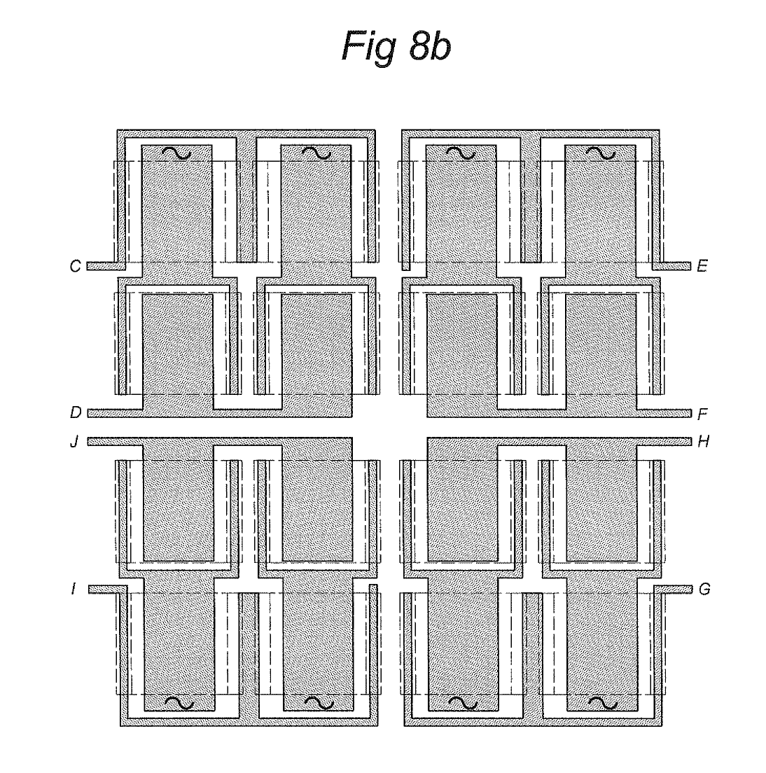

Hereinabove, the invention is described with reference to the preparation of a diode-bridge circuit with four diodes. It will be clear that the invention is not limited to this embodiment. For example, it is similarly possible to prepare a circuitry with four parallel bridge circuits, as shown in FIG. 8a. A possible electric trace pattern enabling this circuitry is shown in FIG. 8b. Here also, electric components according to circuit diagrams as shown in FIGS. 7a-c, could be placed between the connections C-D, E-F, G-H, and I-J.

In the above description the present invention is explained with reference to embodiments in which a layer of p-type semiconductor material is formed in a base substrate of n-type semiconductor-material. It should be clear that, by a proper choice of materials, the reverse is also possible, i.e. a base substrate of p-type semiconductor material containing a layer of n-type semiconductor material.

Furthermore, in the embodiments described, only individual LEDs are shown. It should be clear that, by using the methods described above, also circuits can be prepared comprising one or more so-called duo-LEDs, the properties of which are more fully described in Dutch patent application NL1027961, which is incorporated herein by reference in its entirety.

The above description specifies only a number of possible embodiments of the present invention. It is easy to see that many alternative embodiments of the invention can be envisioned, all of which fall within the scope of the invention. This scope of the invention is defined by the following claims.

1. Method for preparing an electric circuit comprising a plurality of LEDs, said method comprising the steps of:
a) providing a continuous layer of a first semiconductor material;
b) providing a layer of a second semiconductor material in a first pattern, contiguous with the continuous layer;
c) providing a substrate with a layer of a conducting material in a second pattern;
d) attaching the layer of the second semiconductor material in the first pattern to the layer of conducting material in the second pattern; and
e) cutting the continuous layer to form individual LEDs.

2. Method according to claim 1, in which the first semiconductor material is an n-type semiconductor material, and the second semiconductor material is a p-type semiconductor material.

3. Method according to claim 1 or 2, in which the continuous layer is applied on a substrate.

4. Method according to claim 3, in which step e) is performed before step d).

5. Method according to any one of claims 1-4, characterized in that the electric circuit comprises at least one diode-bridge circuit (23).

6. Electric circuit comprising a plurality of LEDs, in which the electric circuit is prepared according to the method according to any one of claims 1-5.

7. Method according to claim 1 for preparing an electric circuit comprising a plurality of LEDs (4,5,6,7), which method comprises the steps of:
providing a first substrate comprising an emitting side and an attachment side, in which the first substrate comprises a first layer (30) of a first semiconductor type and a second layer (31) of a second semiconductor type according to a first pattern, in which the second layer (31) is disposed on the attachment side of the first substrate;
attaching the attachment side of the first substrate to a second substrate (33), the second substrate (33) being insulating and comprising a second pattern of at least one conducting layer (34); and
cutting the first substrate from the emitting side of the first substrate up to the second pattern of the at least one conducting layer (34) according to a third pattern, whereby the plurality of LEDs (4, 5, 6, 7) is formed.

8. Method according to claim 1, in which, before attaching, the attachment side of the first substrate is provided with a fourth pattern of at least one conducting layer (35).

9. Method according to claim 7 or 8, in which the attachment of the first substrate to the second substrate (33) takes place using bumps (40, 41).

10. Method according to claim 9, characterized in that the bumps (40, 41) comprise at least bumps of a first and a second size (40, 41), in which upon attachment the bumps of the first size (40) contact the first layer (30) of the first semiconductor type, and the bumps of the second size (41) contact the second layer (31) of the second semiconductor type.

11. Method according to claim 10, characterized in that the first size is larger than the second size.

12. Method according to any one of claims 7-11, characterized in that at least before cutting, the method further comprises applying a third insulating substrate (38) on the emitting side of the first substrate, the third substrate (38) being transparent for a wavelength that can be generated by at least one of the plurality of LEDs (4, 5, 6, 7).

13. Method according to claim 12, characterized in that the third substrate (38) comprises sapphire.

14. Method according to any one of claims 7-13, in which the second substrate (33) comprises aluminum and is (hard) anodized on at least one side.

15. Method according to any one of the previous claims, characterized in that the first semiconductor type is an n-type conductor, and the second semiconductor type is a p-type conductor.

16. Method according to claim one for preparing an electric circuit comprising a plurality of LEDs (4, 5, 6, 7), in which the method comprises the steps of:
providing a first insulating substrate (50) transparent for a wavelength that can be generated by least one of the plurality of LEDs (4, 5, 6, 7);
forming a layer comprising a first layer (51) of a first semiconductor type and a second layer (52) of a second semiconductor type, on the first insulating substrate (50);
selectively removing the second layer (52) according to a first pattern until a part of the first layer (51) is exposed, and at least by grooves (53) an isolated area (54a, 54b) of the second semiconductor type is formed;
selectively, according to a second pattern, applying at least one conducting layer (55), whereby a first connection with the first layer (51) of the first semiconductor type and a second connection with the isolated area (54a, 54b) of the second semiconductor type is made;
cutting through the at least one conducting layer (55), the second layer (52) of the second semiconductor type and the first layer (51) of the first semiconductor type up to the first insulating substrate (50) according to a third pattern, forming the plurality of LEDs (4, 5, 6, 7); and
attaching the at least one conducting layer (55) on the first insulating substrate (50) to the second insulating substrate (57) comprising a third pattern of at least one conducting layer (59), whereby at least one conducting contact is formed between the at least one conducting layer (55) on the first insulating substrate (50) and the at least one conducting layer (59) on the second insulating substrate (57).

17. Method according to claim 16, characterized in that the first insulating substrate (50) comprises sapphire.

18. Method according to claim 16 or 17, in which the second insulating substrate (57) comprises aluminum and is (hard) anodized on at least one side.

19. Method according to any one of claims 16-18, characterized in that the electric circuit comprises at least one diode-bridge circuit (23).

20. Method according to any one of claims 16-19, characterized in that the first semiconductor type is an n-type conductor, and the second semiconductor type is a p-type conductor.

21. Electric circuit comprising a plurality of LEDs (4, 5, 6, 7), which electric circuit is prepared according to the method according to any one of claims 16-20.
